(19) United States
(12) Patent Application Publication
(10) Pub. No.: US 2010/0328854 A1
(43) Pub. Date: Dec. 30, 2010

(54) COMPONENT, DISPLAY PART STRUCTURE AND PORTABLE TERMINAL DEVICE

(75) Inventors: Junichi Nakao, Tokyo (JP); Yasuyuki Homma, Shizuoka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC CORPORATION, TOKYO (JP)

(21) Appl. No.: 12/449,351

(22) PCT Filed: Feb. 4, 2008
(86) PCT No.: PCT/JP2008/051726

§ 371 Date: Aug. 4, 2009

(51) Int. Cl. H05K 5/02

(52) U.S. Cl. 361/679.01

(57) ABSTRACT

The invention provides a component, a display part structure and a portable terminal device with which breakage of a protecting member can be prevented so as to contribute to further thickness reduction of the portable terminal device. The display part structure of a terminal device includes, in a housing, a display panel used for displaying information; a lighting unit used for irradiating the display panel from a rear face thereof; a protecting member used for protecting the display panel; and a component disposed in the vicinity of at least the protecting member, and an empty space in accordance with a shape of the component is formed in the housing in the vicinity of the protecting member and either of the display panel and the lighting unit. The component has a shape including at least one of a curved face, a bevel face and a face vertical to the protecting member.

### TECHNICAL FIELD

The present invention relates to a component used in a housing equipped with a display part such as a screen, and further relates to a display part structure and a portable terminal device using the component.

### BACKGROUND ART

With respect to portable terminal devices such as cellular phones, a variety of ideas are practiced for achieving a small thickness at the start up of a new model. One of such ideas is thickness reduction of a protecting member used for protecting a display part. Since a protecting member is made of a transparent resin material, however, it is easily broken when its thickness is reduced. Therefore, there has been a limit to the thickness reduction of a protecting member.

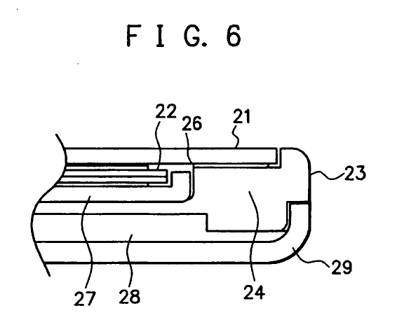

The reason why a protecting member is broken will be described with reference to FIG. 6. FIG. 6 is a side cross-sectional view illustrating a display part structure of a portable terminal device related to the present invention. In the display part structure of the portable terminal device illustrated in FIG. 6, a corner 26 of a flange 24 of an upper casing 23 is given an edge, and the corner 26 is present in the vicinity of a protecting member 21 and a lighting unit 27. Therefore, when external impact or the like is applied, the protecting member 21 hits the corner 26, and hence, stress is concentrated in a portion directly above the corner 26, resulting in breaking the protecting member 21.

An example of the display part structure is a portable communication terminal described in Patent Document 1. In this portable communication terminal, a positioning projection is integrally formed inside a housing, and thus, the strength of the positioning projection is increased so as not to be broken when dropped without causing a failure in the external appearance in molding the housing. In a display part structure employed in this Patent Document 1, a corner is present as an edge in the vicinity of a transparent panel (a protecting member) 34 and a lighting unit 37 as illustrated in FIG. 5 of Patent Document 1. In FIG. 5 of Patent Document 1, the corner corresponds to a leftmost portion of a rib formed as a positioning projection 32d. Therefore, also in the display part structure of Patent Document 1, the transparent panel 34 hits the corner of the positioning projection 32d in the same manner as in the exemplary case illustrated in FIG. 6 when external impact or the like is applied. Therefore, it is apprehended that the transparent panel 34 may be broken due to stress concentrated in a portion directly above the corner.

Patent Document 1: Japanese Patent Application Laid-Open No. 2006-86220

### DISCLOSURE OF THE INVENTION

### Problems to be Solved by the Invention

Accordingly, in the display part structures of the portable communication terminal described in Patent Document 1 and the portable terminal device illustrated in FIG. 6, it is necessary to ease the stress concentration for preventing the breakage of the protecting member.

The present invention was devised in consideration of the aforementioned circumstances, and an exemplary object of the invention is providing a component, a display part structure and a portable terminal device with which breakage of a protecting member can be prevented for consequently contributing to further thickness reduction of the portable terminal device.

### Means for Solving the Problems

In order to achieve the exemplary object, a component in accordance with an exemplary aspect of the invention is included in a terminal device, which includes, in a housing, a display panel used for displaying information, a lighting unit used for irradiating the display panel from a rear face thereof and a protecting member used for protecting the display panel, and the component has a shape allowing an empty space to be formed in the housing in the vicinity of the protecting member and either of the display panel and the lighting unit.

A display part structure in accordance with an exemplary aspect of the invention is a display part structure of a terminal device including, in a housing, a display panel used for displaying information; a lighting unit used for irradiating the display panel from a rear face thereof a protecting member used for protecting the display panel; and a component disposed in the vicinity of at least the protecting member, and an empty space in accordance with a shape of the component is formed in the housing in the vicinity of the protecting member and either of the display panel and the lighting unit.

A portable terminal device in accordance with an exemplary aspect of this invention includes the aforementioned component of the invention or the aforementioned display part structure of the invention.

### EFFECTS OF THE INVENTION

According to the present invention, breakage of a protecting member can be prevented, so as to consequently contribute to further thickness reduction of a portable terminal device.

### BEST MODE FOR CARRYING OUT THE INVENTION

Best modes for carrying out the present invention will now be described in detail with reference to the accompanying drawings.

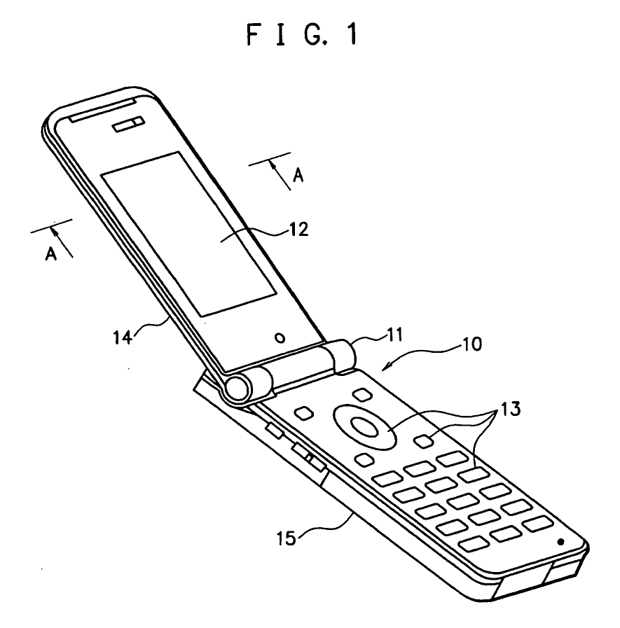

First, as a portable terminal device according to an exemplary embodiment of the invention, a folding cellular phone 10 will be described. FIG. 1 is a perspective view illustrating the external appearance of the folding cellular phone of the exemplary embodiment. As illustrated in FIG. 1, in the folding cellular phone 10 of this embodiment, an upper housing 14 including a display part 12 and a lower housing 15 including a button part 13 used for various operations are foldably connected to each other through a hinge part 11. FIG. 1 illustrates a state where the housings are opened on an axis of the hinge part 11. Although the folding cellular phone is described in the exemplary embodiment, the invention is not limited to this but is applicable to any terminal device having a housing equipped with a display part structure.

Now, exemplary embodiments 1 through 4 with regard to the display part structure of the folding cellular phone having the aforementioned structure of the exemplary embodiment will be described as follows:

### Exemplary Embodiment 1

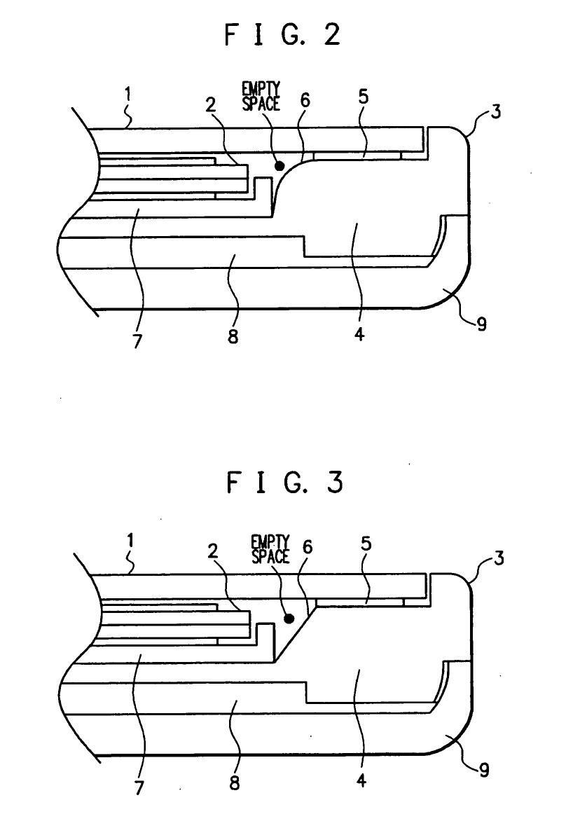

FIG. 2 is a side cross-sectional view of a display part structure of the folding cellular phone 10 of FIG. 1, in which a cross-section of the upper housing 14 taken on line A-A of FIG. 1 is partly illustrated.

As illustrated in FIG. 2, the display part structure of an exemplary embodiment 1 includes a protecting member (a transparent panel) 1, a liquid crystal (a display panel) 2, a lighting unit (a lighting means) 7 and an upper casing (a component) 3. The protecting member (the transparent panel) 1 is made of a transparent resin material or the like, and protects the liquid crystal 2 from external impact, dust or the like. The liquid crystal 2 displays various information of characters and images. The lighting unit 7 irradiates the liquid crystal 2 from the rear face thereof. The lighting unit 7, the liquid crystal 2 and the protecting member 1 are successively incorporated in the upper casing 3. It is noted that the protecting member 1 corresponds to the display part 12 illustrated in FIG. 1.

Furthermore, as illustrated in FIG. 2, the upper casing 3 has a flange 4 and a corner 6. The upper casing 3 corresponds to an exemplary embodiment of the component according to the present invention. Although the upper casing 3 is a component exposed to the outside and corresponding to the top portion of the upper housing 14 as illustrated in FIG. 2 in the exemplary embodiment 1 (and exemplary embodiments 2 through 4 described later), the upper casing is not limited to such a component. Instead, the upper casing 3 may be, for example, a component not exposed to the outside of the housing but included in the housing. Furthermore, although the upper casing 3 is a component holding the lighting unit 7 and the protecting member 1 as illustrated in FIG. 2 in the exemplary embodiment 1 (and exemplary embodiments 2 through 4 described later), it need not always hold the lighting unit 7 and the protecting member 1 as long as the upper casing 3 may be, for example, disposed in the vicinity of the lighting unit 7 and the protecting member 1. Alternatively, the upper casing 3 may only be, for example, disposed in the vicinity of the liquid crystal 2 and the protecting member 1.

Moreover, as illustrated in FIG. 2, the protecting member 1 is fixed on the upper casing 3 with a double-sided adhesive tape (a fixing means) 5 adhered onto an outer face of the flange 4 of the upper casing 3.

Furthermore, as illustrated in FIG. 2, a substrate/mounting part 8 on which a substrate and components are mounted is provided below the upper casing 3. A lower casing 9 is provided below the substrate/mounting part 8.

In the display part structure of the exemplary embodiment 1, as illustrated in FIG. 2, the upper casing 3 has a rounded curved shape in its portion disposed in the vicinity of the protecting member 1, the liquid crystal 2 and the lighting unit 7 (specifically, at the corner 6 disposed at the upper left of the flange 4 in FIG. 2). This curved shape forms an empty space between the protecting member 1/the lighting unit 7 and the corner 6. Even when the protecting member 1 is pressed by an external force, the protecting member 1 can be prevented from hitting the corner 6 of the upper casing 3 owing to this empty space, resulting in easing stress concentration and preventing breakage of the protecting member 1.

### Exemplary Embodiment 2

FIG. 3 is a side cross-sectional view of a display part structure of the folding cellular phone 10 illustrated in FIG. 1, in which a cross-section of the upper housing 14 taken on line A-A of FIG. 1 is partly illustrated. Since elements 1 through 9 illustrated in FIG. 3 respectively correspond to the elements 1 through 9 illustrated in FIG. 2 and described in the exemplary embodiment 1, the description is herein omitted.

In the display part structure of an exemplary embodiment 2, the upper casing 3 has a bevel shape in its portion disposed in the vicinity of the protecting member 1, the liquid crystal 2 and the lighting unit 7 (specifically, at the corner 6 disposed at the upper left of the flange 4 in FIG. 3). This bevel shape forms an empty space between the protecting member 1/the lighting unit 7 and the corner 6. Even when the protecting member 1 is pressed by an external force, the protecting member 1 can be prevented from hitting the corner 6 of the upper casing 3 owing to this empty space, resulting in easing stress concentration and preventing breakage of the protecting member 1.

### Exemplary Embodiment 3

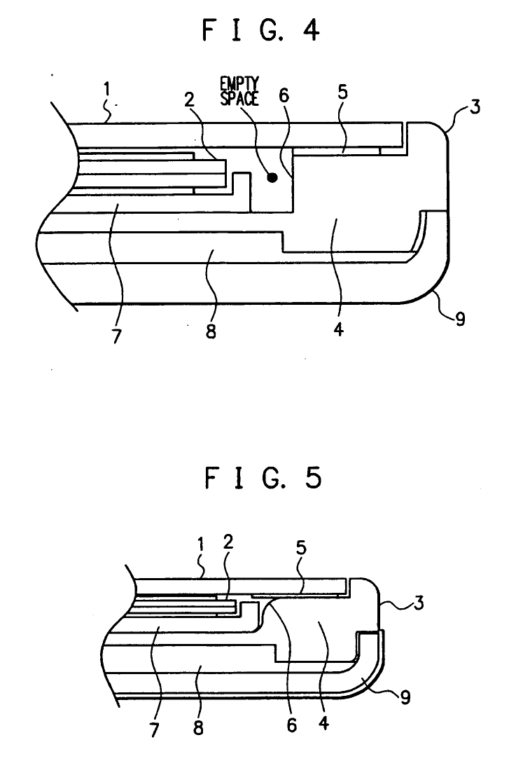

FIG. 4 is a side cross-sectional view of a display part structure of the folding cellular phone 10 illustrated in FIG. 1, in which a cross-section of the upper housing 14 taken on line A-A of FIG. 1 is partly illustrated. Since elements 1 through 9 illustrated in FIG. 4 respectively correspond to the elements 1 through 9 illustrated in FIG. 2 and described in the exemplary embodiment 1, the description is herein omitted.

In the display part structure of an exemplary embodiment 3, the upper casing 3 has a shape vertical to the left end of the double-sided adhesive tape 5 and the protecting member 1 and perpendicular to a direction extended horizontally from the bottom of the lighting unit 7 in its portion disposed in the vicinity of the protecting member 1, the liquid crystal 2 and the lighting unit 7 (specifically, at the corner 6 disposed at the upper left of the flange 4 in FIG. 4). This shape forms an empty space between the protecting member 1/the lighting unit 7 and the corner 6. Even when the protecting member 1 is pressed by an external force, the protecting member 1 can be prevented from hitting the corner 6 of the upper casing 3 owing to this empty space, resulting in easing stress concentration and preventing breakage of the protecting member 1.

As described so far, according to the exemplary embodiments 1 through 3 of this invention, an edge is eliminated from the shape of the upper casing in the vicinity of the protecting member and the lighting unit, and an empty space is formed between the protecting member 1/the lighting unit 7 and the corner 6. Accordingly, the breakage of the protecting member can be prevented, resulting in contributing further thickness reduction of the portable terminal device.

Moreover, according to the exemplary embodiments 1 through 3 of this invention, since an edge is eliminated from the shape of the upper casing in the vicinity of the protecting member and the lighting unit, an area of the flange where the double-sided adhesive tape is adhered is reduced, resulting in contributing to the cost reduction.

It is noted that the shape of the upper casing in the portion disposed in the vicinity of the protecting member and the lighting unit is not limited to those described in the exemplary embodiments 1 through 3 but any shape can be employed as far as an empty space can be formed between the protecting member 1/the lighting unit 7 and the corner 6. For example, an empty space may be formed by arbitrarily combining the respective shapes (such as the curved shape and the bevel shape) of the corner 6 of the upper casing described in the exemplary embodiments 1 through 3. Also, the empty space is formed between the protecting member 1/the lighting unit 7 and the corner 6, which does not limit the invention. For example, the empty space may be formed between the protecting member 1/the liquid crystal 2 and the corner 6. In other words, the empty space is formed in the vicinity of the protecting member 1 and either of the liquid crystal 2 and the lighting unit 7.

### Exemplary Embodiment 4

FIG. 5 is a side cross-sectional view of a display part structure of the folding cellular phone 10 illustrated in FIG. 1, in which a cross-section of the upper housing 14 taken on line A-A of FIG. 1 is partly illustrated. Since elements 1 through 9 illustrated in FIG. 5 respectively correspond to the elements 1 through 9 illustrated in FIG. 2 and described in the exemplary embodiment 1, the description is herein omitted.

In the display part structure of an exemplary embodiment 4, the upper casing 3 has a curved shape in its portion disposed in the vicinity of the protecting member 1, the liquid crystal 2 and the lighting unit 7 (specifically, at the corner 6 disposed at the upper left of the flange 4 in FIG. 5) in the same manner as in the exemplary embodiment 1, but a way to adhere the double-sided adhesive tape 5 is different from that employed in the exemplary embodiment 1.

In the display part structure of the exemplary embodiment 4, the double-sided adhesive tape 5 is adhered, as illustrated in FIG. 5, so as to extend on the protecting member 1 to be close to the lighting unit 7 and to cover the empty space formed between the protecting member 1/the lighting unit 7 and the corner 6. Since the double-sided adhesive tape 5 is adhered to be thus extended on the protecting member 1, the stress concentration can be further eased, and therefore, the effect to prevent the breakage of the protecting member 1 can be expected further.

The way to adhere the double-sided adhesive tape 5 of the exemplary embodiment 4 may be employed in the exemplary embodiments 2 and 3.

As described so far, according to the exemplary embodiment 4 of this invention, an edge is eliminated from the shape of the upper casing in the vicinity of the protecting member and the lighting unit, and the double-sided adhesive tape is adhered to extend on the protecting member to be close to the lighting unit, resulting in further definitely preventing the breakage of the protecting member.

The exemplary embodiments of the present invention have been described, and the invention is not limited to the above description but may be variously modified without departing from the spirit of the invention.

This application is based upon and claims the benefit of priority from Japanese patent application No. 2007-025469, filed on Feb. 5, 2007, the disclosure of which is incorporated herein in its entirety by reference.

### INDUSTRIAL APPLICABILITY

The present invention is applicable to any device or equipment including a housing equipped with a display part.

### DETAILED DESCRIPTION OF THE DRAWINGS

FIG. 1 is a perspective view illustrating the external appearance of a portable terminal device according to an exemplary embodiment of the invention.

FIG. 2 is a side cross-sectional view illustrating a display part structure of the portable terminal device of FIG. 1 according to an exemplary embodiment 1.

FIG. 3 is a side cross-sectional view illustrating a display part structure of the portable terminal device of FIG. 1 according to an exemplary embodiment 2.

FIG. 4 is a side cross-sectional view illustrating a display part structure of the portable terminal device of FIG. 1 according to an exemplary embodiment 3.

FIG. 5 is a side cross-sectional view illustrating a display part structure of the portable terminal device of FIG. 1 according to an exemplary embodiment 4.

FIG. 6 is a side cross-sectional view illustrating an exemplary display part structure of a portable terminal device related to the present invention.

### DESCRIPTION OF REFERENCE NUMERALS

1, 21 protecting member (transparent panel)
2, 22 liquid crystal (display panel)
3, 23 upper casing (member)
4, 24 flange
5 double-sided adhesive tape (fixing means)
6, 26 corner
7, 27 lighting unit (lighting means)
8, 28 substrate/component mounting part
9, 29 lower casing
10 folding cellular phone (portable terminal device)
11 hinge part
12 display part
13 button part
14 upper housing
15 lower housing

1. A component included in a terminal device, the terminal device including, in a housing, a display panel used for displaying information, a lighting unit used for irradiating the display panel from a rear face thereof and a protecting member used for protecting the display panel,
the component including a shape allowing an empty space to be formed in the housing in the vicinity of the protecting member and either of the display panel and the lighting unit.

2. The component according to claim 1,
wherein the component includes, as a shape allowing the empty space to be formed, at least one of a curved face, a bevel face and a face vertical to the protecting member.

3. A display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit.

4. The display part structure according to claim 3,
wherein the component includes, as a shape allowing the empty space to be formed, at least one of a curved face, a bevel face and a face vertical to the protecting member.

5. The display part structure according to claim 3, further comprising a fixing part used for fixing the protecting member on the component,
wherein the fixing part is provided on the protecting member in such a manner as to cover the empty space.

6. A portable terminal device comprising the component according to claim 1 or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit.

7. The display part structure according to claim 4, further comprising a fixing part used for fixing the protecting member on the component,
wherein the fixing part is provided on the protecting member in such a manner as to cover the empty space.

8. A portable terminal device comprising the component according to claim 2, or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit.

9. A portable terminal device comprising the component according to claim 1 or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit; and
wherein the component includes, as a shape allowing the empty space to be formed, at least one of a curved face, a bevel face and a face vertical to the protecting member.

10. A portable terminal device comprising the component according to claim 2 or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit; and
wherein the component includes, as a shape allowing the empty space to be formed, at least one of a curved face, a bevel face and a face vertical to the protecting member.

11. A portable terminal device comprising the component according to claim 1 or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit; further comprising a fixing part used for fixing the protecting member on the component,
wherein the fixing part is provided on the protecting member in such a manner as to cover the empty space.

12. A portable terminal device comprising the component according to claim 2 or a display part structure of a terminal device comprising, in a housing:
a display panel used for displaying information;
a lighting unit used for irradiating the display panel from a rear face thereof;
a protecting member used for protecting the display panel; and
a component disposed in the vicinity of at least the protecting member,
wherein an empty space in accordance with a shape of the component is formed in the housing in the vicinity of the protecting member and either of the display panel and the lighting unit; further comprising a fixing part used for fixing the protecting member on the component,
wherein the fixing part is provided on the protecting member in such a manner as to cover the empty space.
